(19) United States
(12) Patent Application Publication
(10) Pub. No.: US 2010/0112488 A1
(43) Pub. Date: May 6, 2010

(54) METHOD FOR FORMING MICROLENS OF IMAGE SENSOR AND METHOD FOR MANUFACTURING THE IMAGE SENSOR

(76) Inventor: MYUNG SOO KIM, Gyeongsangnam-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/608,237

(22) Filed: Oct. 29, 2009

(30) Foreign Application Priority Data
Nov. 5, 2008 (KR) 10-2008-0109295

(51) Int. Cl. G03F 7/20

(52) U.S. Cl. 430/319; 430/321

(57) ABSTRACT

Methods of forming a microlens are disclosed. In one embodiment, a method for forming a microlens of an image sensor includes: coating a photoresist for forming microlenses on a substrate of an image sensor; allowing laser light to be incident on the inside of the photoresist to create a standing wave, the laser light affecting portions of the photoresist positioned in the amplitude range of the laser light; and forming microlenses by curing the photoresist having the laser light affected portions. With the proposed method for forming the microlens, various sizes of microlenses can be formed and fine size of microlenses can be formed by, for example, adjusting the wavelength of the laser light.

### CROSS-REFERENCE TO RELATED APPLICATION

This application claims the benefit under 35 U.S.C.§119 of Korean Patent Application No. 10-2008-0109295, filed Nov. 5, 2008, which is hereby incorporated by reference in its entirety.

### BACKGROUND

Generally, an image sensor is defined as a semiconductor device that converts an optical image into an electrical signal. Typical image sensors include charge-coupled device (CCD) image sensors and complementary metal oxide semiconductor (CMOS) image sensors.

An image sensor is generally manufactured by forming transistors and photodiodes that are connected electrically to the transistors on a semiconductor substrate, forming a dielectric structure and wirings on the transistors and the photodiodes, and then forming red, green, and blue color filters on the dielectric structure.

Herein, when the thickness of the red, green, and blue color filters formed on the upper surface of the dielectric structure are different from each other, a photosensitive material may be coated on the upper surface of the color filters to form a planarization layer, and a photoresist film is coated on the upper surface of the planarization layer, patterned, and subject to a reflow process, thereby forming microlenses that provide converged light to the photodiodes in the portions corresponding to the respective color filters.

The microlens is one of the important elements in determining the performance of an image sensor. In the related art, an angular microlens pattern is typically formed and heated to cause the pattern to become in a fluid state as part of the reflow process, which results in a hemisphere shape that is then cooled, thereby manufacturing the microlens.

Though such a method is advantageous in view of the low-priced material being used and simple fabrication process, the related art method suffers from low reproducibility.

Meanwhile, as another method, a microlens shape is formed through affecting the light pattern on the photosensitive film for the microlenses. Here, light intensity passing through regions of a lithography mask is affected by differing the area of a clear region of the lithography mask depending on the radius of a microlens. Though such a method may have an advantage in that the reproducibility is better compared to the previous case, this method has a disadvantage in that the shape of the clear region of the mask is very complicated.

Moreover, there is a limitation in reducing the size of the microlens when using these methods. Accordingly, there is a demand for a method for forming a microlens capable of achieving the goal for ultra-miniaturization of a semiconductor device.

### BRIEF SUMMARY

Embodiments of the present invention provide a method for forming a microlens of an image sensor, in a smaller size, compared to the related art.

A method for forming a microlens of an image sensor according to one embodiment includes: coating a photoresist for forming microlenses on a substrate; allowing laser light to be incident within the photoresist across an entire length of the photoresist, the laser light affecting portions of the photoresist positioned in the amplitude range of the laser light; and forming microlenses by curing the photoresist, the microlenses being formed of the regions of the photoresist positioned in the amplitude range of the laser light.

A method for manufacturing an image sensor according to another embodiment, includes: forming an interlayer dielectric layer on a semiconductor substrate on which a plurality of photodiodes are formed; forming a color filter layer over the interlayer dielectric layer; coating a photoresist on the color filter layer; allowing a first light having a first phase to be incident on the inside of the photoresist horizontally across the photoresist; allowing a second light having the same wavelength as the first light but having a second phase inverse to the first phase to be incident on the photoresist horizontally across the photoresist, whereby regions exposed to the first light and the second light form microlenses.

A method for manufacturing an image sensor according to yet another embodiment includes: forming a material layer for forming microlenses on a substrate; and performing a patterning process of the material layer by allowing light to be incident a first side surface of the material layer, wherein the light passes horizontally through the material layer to a second side surface of the material layer, and enabling light to be incident the second surface of the material layer and pass horizontally through the material layer to the first side surface of the material layer.

In accordance with embodiments of the present invention, the light incident the second surface of the material layer is reflected on the second side surface or the outside of the second side surface to form a standing wave in the material layer as it passes horizontally through the material layer to the first side surface of the material layer.

According to one embodiment, a reflective layer that reflects the light on the second side surface of the material layer is formed to allow the light to be reflected on the interface between the reflective layer and the material layer, enabling light to be incident the second surface of the material layer.

According to another embodiment, a reflection mirror that reflects the light is disposed to contact the second side surface of the material layer to allow the light to be reflected on the reflecting surface of the reflection minor, enabling light to be incident the second surface of the material layer.

According to an embodiment, when the light is reflected on the outside of the second side surface, the reflecting surface of the reflection mirror that reflects the light is disposed to be opposed to the second side surface of the material layer to allow the light to be reflected on the reflecting surface.

### BRIEF DESCRIPTION OF THE DRAWINGS

FIGS. 1 to 5 are cross-sectional views for explaining a method for manufacturing an image sensor according to an embodiment.

FIGS. 6 and 7 are view for explaining a method for forming a microlens according to an embodiment.

### DETAILED DESCRIPTION

Hereinafter, the proposed embodiments will be described in detail with reference to the accompanying drawings. However, the scope of the invention is not limited to the embodiments explicitly described herein.

Hereinafter, the term “including” will not exclude the existence of components or steps other than those illustrated. In addition, the thickness of several layers and regions may be enlarged in the accompanying drawings in order to clarify them. The same reference numbers will be used throughout the drawings to refer to the same or like parts. In the description of an embodiment, when an element such as a layer, film, area, plate or the like is described as being formed “on” another element, it can be understood as being “directly” contacted to the other element or other layers, films, area, or the like may be formed therebetween.

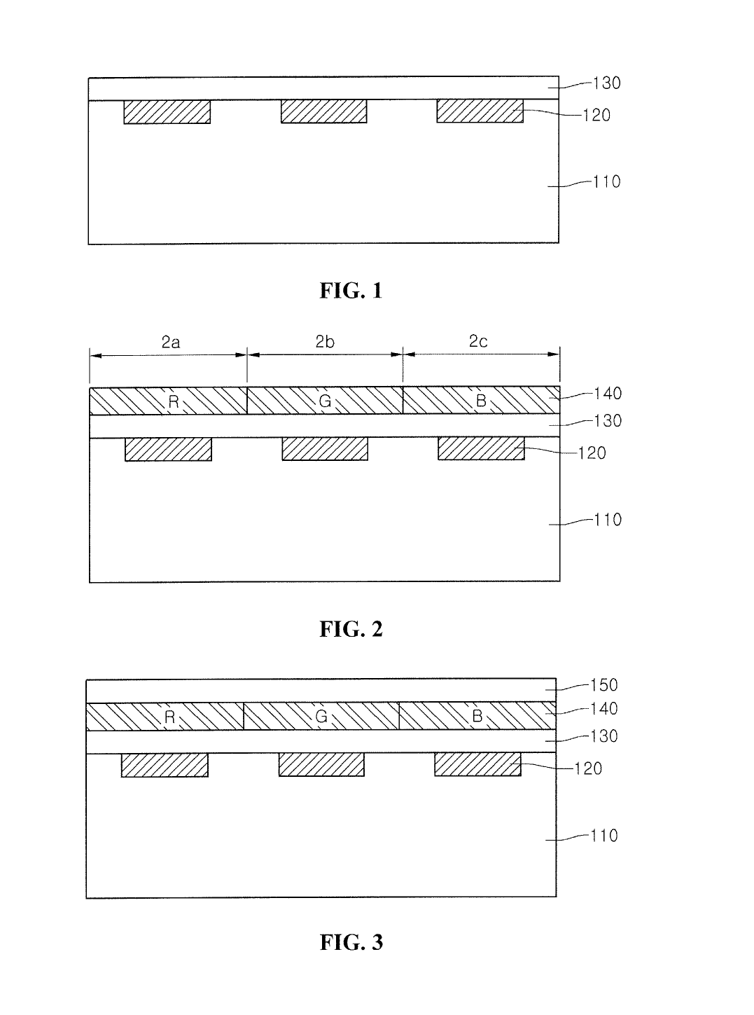

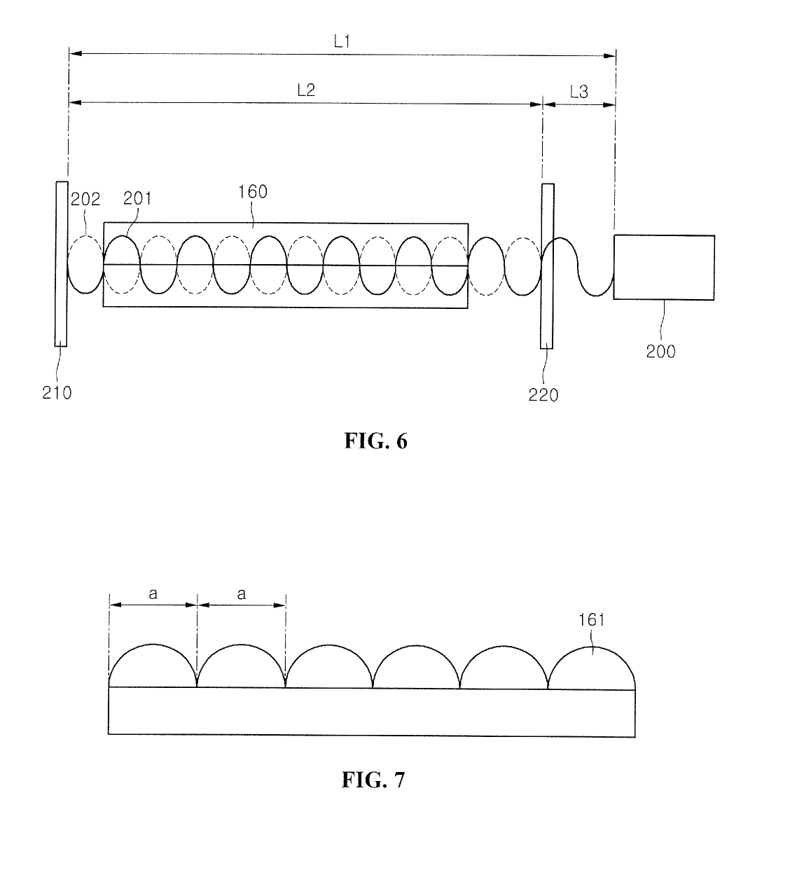

FIGS. 1 to 5 are cross-sectional views explaining a method for manufacturing an image sensor according to an embodiment, and FIGS. 6 and 7 are views for explaining a method for forming a microlens using a laser wavelength according to an embodiment.

First, referring to FIG. 1, an interlayer dielectric layer 130 is formed on a semiconductor substrate 110 on which a plurality of photodiodes 120 are formed. The interlayer dielectric layer 130 may be formed in multilayers.

Although not shown, several metal patterns may further be formed between the photodiodes 120 and the interlayer dielectric layer 130. Circuitry and photodiode type and arrangement may vary, but the method for forming the microlens according to embodiments of the present invention can be applied to various image sensors so that it is not limited to that shown in the drawing.

Next, referring to FIG. 2, a color filter layer 140 having color filters corresponding to the photodiodes 120 is formed over the interlayer dielectric layer 130.

The color filter layer 140 can include red R, green G, and blue B color filters that filter light per each corresponding wavelength-range and can be formed using dyeable resist that is coated, exposed, and developed.

In particular, according to an embodiment of the present invention, the horizontal lengths 2a, 2b, and 2c of the respective color filters of the color filter layer 140 may be formed in a half-wavelength size of a laser wave to be described later. This allows for ease of alignment of the respective color filters to the respective microlenses, since the horizontal lengths of the microlenses formed on the color filter layer 140 are formed in a half-wavelength size of the laser wave.

Next, referring to FIG. 3, a planarization layer 150 may be formed over the color filter layer 140.

The planarization layer 150 can be formed over the semiconductor substrate 110 including the color filter layer 140 to protect the devices below from infiltration of moisture or heavy metals from the outside. In one embodiment, the planarization layer 150 can be formed of a silicon nitride layer.

In the image sensor, because optical transmission is important, the thickness of the planarization layer 150 is selected to inhibit interference. For example, according to an embodiment, the planarization layer 150 may be formed at a thickness of 1000 to 6000 Å to reduce the interference caused by thin films.

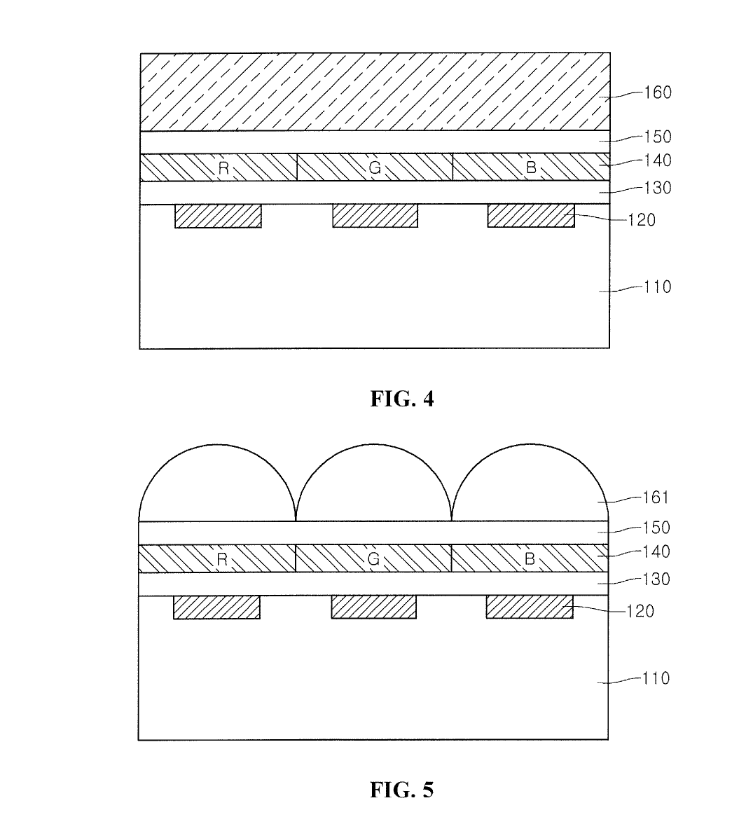

Next, referring to FIG. 4, a photoresist 160 for forming microlenses is coated over the planarization layer 150.

The thickness of the photoresist 160 may be formed to be larger than the amplitude of the laser wave to be described later. In particular, in order for the photoresist in the region where a standing wave by the laser wave is formed to remain, the photoresist 160 can be formed of a negative photoresist where only a portion receiving light remains after being developed.

The method for forming the microlens 161 using laser in a state where the negative photoresist is coated will be described in more detail with reference to FIGS. 6 and 7.

FIG. 6 shows a representational diagram with a cross-sectional view of an image sensor (such as the device shown at the method step corresponding to FIG. 5) for explaining a method for forming a microlens according to an embodiment. FIG. 7 shows a cross-sectional view of an image sensor having microlenses formed in accordance with an embodiment of the present invention after performing development process. Referring to FIG. 6, the microlens can be formed by directing light horizontally across the wafer in a state where the negative photoresist 160 is coated on the substrate (see reference 110 of FIG. 5) according to the embodiment of the present invention.

More specifically, in order to manufacture the microlens 161 in the image sensor, the substrate having the photoresist 160 coated thereon is arranged between a reflection mirror 210 and a laser generator 200.

The laser generator 200 sets the wavelength of the laser light intended to be emitted in consideration of the size (horizontal length) of the microlens intended to be manufactured. In other words, the laser generator 200 emits the laser light having the wavelength of two times of the size of the microlens 161 intended to be manufactured.

The reflection mirror 210 serves to allow the laser light 210 emitted from the laser generator 200 to form a standing wave after being reflected from the reflection mirror 210. A transmission mirror 220 may be further provided between the semiconductor substrate coated with the photoresist 160 and the laser generator 200.

When the distance from the laser emitting surface of the laser generator 200 to the reflecting surface of the reflection mirror 210 is L1, the distance L1 should be an integer multiple of the emitted laser wavelength.

By making the distance L1 an integer multiple of the emitted laser wavelength, the laser light emitted from the laser generator 200 can form the standing wave in the photoresist 160 after being reflected on the reflection mirror 210.

When the distance from the laser emitting surface of the laser generator 200 to the transmission mirror 220 is L3, and if the distance L3 is also made an integer multiple of the emitted laser wavelength, the distance L2 from the transmission mirror 200 to the reflecting surface of the reflection mirror 210 should also be an integer multiple of the laser wavelength in order to form the standing wave of the laser in the photoresist 160.

In other words, the laser light (first light 201 shown with a bold line) emitted from the laser generator 200 is reflected on the reflecting surface of the reflection mirror 210 (second light 202 shown with a dotted line), after passing through the inside of the photoresist 160, and then is emitted again to the photoresist 160. Thereby, the standing wave is formed in the photoresist 160 by the first light and the second light, having the same wavelength and amplitude but inverse phases.

The standing wave is formed in the photoresist 160 using a principle that waves are overlapped as two waves having the same wavelength, amplitude, and period are proceeded from different directions. Accordingly, in the photoresist 160, the region belonging to the amplitude range of the standing wave (where the light passes) is cured and other photoresist regions can be removed by the development process to be proceeded thereafter.

Therefore, in the negative photoresist, the outer regions other than the amplitude range of the standing wave is not cured to be removed, making it possible to form microlenses 161 having the half-radius size of the laser light (i.e. has a diameter that is half the wavelength of the laser light).

The microlens 161 manufactured through the above described method can be formed in the same size (horizontal length), as shown in FIG. 7. Meanwhile, the size of the color filter layer corresponding to the microlens 161 is also formed having the half-radius size of the laser light to enable suitable positioning of the microlenses over the color filters (and corresponding pixels).

Although the photoresist 160 is described as the material layer used for forming the microlens 161, embodiments are not limited thereto. For example, various sorts of materials can be used in accordance with the present invention if they light-curable (by, for example, laser light).

According to an embodiment, the reflection mirror 210 can be disposed to contact the side surface (a second side surface opposite a first side surface facing the laser light source) of the photoresist 160 and the distance from the emitting surface of the laser light to the second side surface of the photoresist 160 or the reflecting surface of the reflection mirror 210 can be arranged at the integer multiple of the wavelength of the laser light so that the laser light is incident on the first side surface of the photoresist 160 and then is reflected on the second side surface, thereby forming the standing wave.

According to one embodiment, a reflective layer can be formed on the side surface of the photoresist 160 instead of a separate reflection mirror. The reflective layer can be any suitable material capable of causing a light reflection. Therefore, even when forming a reflective layer formed of material that can cause a light reflection on the second side surface of the photoresist 160 instead of the reflection minor 210, the light is reflected on the second side surface of the photoresist 160, thereby making it possible to form the standing wave in the photoresist 160.

With the proposed methods for forming the microlens, the microlens is formed in the half-radius size of the laser light, having an advantage in that the size of the microlens intended to be manufactured can be changed by changing the wavelength of the laser light. In other words, more various sizes of microlenses can be formed and more fine size of microlenses can be formed as compared to related art microlens fabrication methods.

The semiconductor devices of the present invention are applicable to a broad range of semiconductor devices technologies and can be fabricated from a variety of semiconductor materials. The following description discusses several presently preferred embodiments of the semiconductor devices of the present invention as implemented in silicon substrates, since the majority of currently available semiconductor devices are fabricated in silicon substrates and the most commonly encountered applications of the present invention will involve silicon substrates. Nevertheless, the present invention may also advantageously be employed in silicon on insulator (SOI), germanium, and other semiconductor materials. Accordingly, the present invention is not intended to be limited to those devices fabricated in silicon semiconductor materials, but will include those devices fabricated in one or more of the available semiconductor materials and technologies available to those skilled in the art, such as thin-film-transistor (TFT) technology using polysilicon on glass substrates.

It should be noted that the drawings are not true to scale. Further, various parts of the active elements have not been drawn to scale. Certain dimensions have been exaggerated in relation to other dimensions in order to provide a clearer illustration and understanding of the present invention.

In addition, although the embodiments illustrated herein are shown in two-dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present invention is illustrated by preferred embodiments directed to active devices, it is not intended that these illustration be a limitation on the scope or applicability of the present invention. It is not intended that the active devices of the present invention be limited to the physical structures illustrated. These structures are included to demonstrate the utility and application of the present invention to presently preferred embodiments.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to utilize or combine such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for forming microlenses of an image sensor, comprising:
coating a photoresist for forming microlenses on a substrate for the image sensor;
allowing laser light to be incident on the inside of the photoresist in a horizontal direction, the laser light affecting portions of the photoresist positioned in the amplitude range of the laser light; and
forming microlenses by curing the photoresist having the laser light affected portions.

2. The method for forming the microlenses of the image sensor according to claim 1, wherein the photoresist is a negative photoresist.

3. The method for forming the microlenses of the image sensor according to claim 1, wherein the allowing laser light to be incident on the inside of the photoresist comprises allowing a standing wave of the laser light to be formed in the photoresist.

4. The method for forming the microlenses of the image sensor according to claim 1, wherein the microlens is formed in a half-radius size of the laser light.

5. A method for manufacturing an image sensor, comprising:
forming an interlayer dielectric layer on a semiconductor substrate on which a plurality of photodiodes are formed;
forming a color filter layer over the interlayer dielectric layer;
coating a photoresist on the color filter layer;
allowing a first light having a first phase to be incident on the inside of the photoresist horizontally across the photoresist;
allowing a second light having the same wavelength as the first light but having a second phase inverse to the first phase to be incident on the photoresist horizontally across the photoresist; and
forming microlenses from regions of the photoresist exposed to the first light and the second light.

6. The method for manufacturing the image sensor according to claim 5, wherein the second light is the first light that is reflected from a reflecting surface that faces an outer side surface of the photoresist.

7. The method for manufacturing the image sensor according to claim 6, wherein the distance between an emitting surface that emits the first light and the reflecting surface is an integer multiple of the wavelength of the first light.

8. The method for manufacturing the image sensor according to claim 5, wherein the horizontal length of the microlens is the half-radius size of the first light or the second light.

9. A method for manufacturing an image sensor, comprising:
forming a material layer for forming microlenses on a substrate of an image sensor; and
performing a patterning process of the material layer by enabling light to be incident a first side surface of the material layer, and enabling light to be incident a second side surface of the material layer that is opposite the first side surface of the material layer, wherein the light passes horizontally through the material layer between the first side surface and the second side surface.

10. The method for manufacturing the image sensor according to claim 9, wherein enabling light to be incident the second side surface of the material layer comprises providing a reflective surface to provide light having opposite phase to the light incident the first side surface of the material layer, thereby forming a standing wave in the material layer.

11. The method for manufacturing the image sensor according to claim 10, wherein providing the reflective surface comprises providing a reflective layer on the second side surface of the material layer, the reflective layer, allowing the light incident the first side surface to be reflected on the interface between the reflective layer and the material layer.

12. The method for manufacturing the image sensor according to claim 10, wherein providing the reflective surface comprises providing a reflection mirror in contact with the second side surface of the material layer, allowing the light incident the first side surface to be reflected on the reflecting surface of the reflection mirror.

13. The method for manufacturing the image sensor according to claim 10, wherein providing the reflective surface comprises providing a reflection mirror having the reflective surface facing the second side surface of the material layer, allowing the light incident the first side surface to be reflected on the reflecting surface of the reflection mirror.

14. The method for manufacturing the image sensor according to claim 10, further comprising selecting the wavelength and the amplitude of the light according to a desired size of the microlens, the selected wavelength of the light providing the diameter of the microlens.
